(19) United States
(12) Patent Application Publication
(10) Pub. No.: US 2026/0351990 A1
(43) Pub. Date: Nov. 5, 2026

(54) Charging and Power Supplying Device and Wind Power Generation System

(71) Applicants: Energy Innovations Japan Co., Ltd., Tokyo (JP); i-Formula LLC, Uda-shi (JP); BMI Co., Ltd., Tokyo (JP)

(72) Inventor: Masami Tanaka, Tokyo (JP)

(21) Appl. No.: 19/654,707

(22) Filed: Apr. 22, 2026

Related U.S. Application Data
(60) Provisional application No. 63/798,127, filed on May 1, 2025.

(30) Foreign Application Priority Data
Jul. 9, 2025 (JP) 2025-116152

(51) Int. Cl. H02J 7/35; H01M 10/46; H01M 10/627; H02J 7/00; H02J 7/70; H10F 77/30; H02J 101/28

(52) U.S. Cl. CPC H02J 7/35; H01M 10/465; H01M 10/627; H02J 7/751; H02J 7/855; H10F 77/311; H02J 2101/28; H02J 2207/40

(57) ABSTRACT

A charging and power supplying device attachable to a columnar body is disclosed. The device includes a tubular battery that coaxially covers an outer circumferential surface of the columnar body, a power generator that covers an outer circumferential surface of the battery, and a power supplying unit configured to supply electric power from the battery to an external device. The battery is charged by electric power generated at least by the power generator. A wind power generation system including the charging and power supplying device is also disclosed.

### REFERENCE TO RELATED APPLICATIONS

This non-provisional application claims priority under 35 U.S.C. §119(e) to U.S. Provisional Application No. 63/798,127, filed May 1, 2025, and under 35 U.S.C. §119(a) to Japanese Patent Application No. 2025-116152, filed Jul. 9, 2025, which claims priority to the U.S. Provisional Application No. 63/798,127, the entire contents of each of which are incorporated herein by reference.

### BACKGROUND

The present disclosure relates to a charging and power supplying device and a wind power generation system.

For example, the charging and power supplying device described in Japanese Patent Application Laid-Open Publication No. 2020-191728 is provided with a battery, an input terminal and an output terminal. The battery is powered from an external power supply (e.g., commercial power utilities) via the input terminal and is charged with the supplied power. The power output from the battery is supplied to an external device through the output terminal.

### SUMMARY

There is a demand for a charging and power supplying device and a wind power generation system that can improve convenience.

An object of the present disclosure is to provide a charging and power supplying device and a wind power generation system that can improve convenience.

A charging and power supplying device according to the present disclosure is configured to be attached to a columnar body. The charging and power supplying device comprises a tubular battery that coaxially covers an outer circumferential surface of the columnar body; a power generator that covers an outer circumferential surface of the battery; and a power supplying unit that supplies electric power from the battery to an external device. The battery is charged by electric power generated by at least the power generator.

According to another aspect of the present disclosure, a wind power generation system comprises a wind turbine generator supported by a columnar body; and a charging and power supplying device configured to be attached to the columnar body. The charging and power supplying device comprises a tubular battery that coaxially covers an outer circumferential surface of the columnar body, a power generator that covers an outer circumferential surface of the battery, a power supplying unit that supplies electric power from the battery to an external device, and a power reception unit that receives electric power from the wind turbine generator to charge the battery. The battery is charged by electric power generated by at least the power generator.

The above and further objects and features will more fully be apparent from the following detailed description with accompanying drawings.

### BRIEF DESCRIPTION OF DRAWINGS

FIG. 1 is a perspective view schematically illustrating the configuration of a wind power generation system according to an embodiment.

FIG. 2 is a block diagram schematically illustrating the configuration of the wind power generation system.

FIG. 3 is a cross-sectional view schematically illustrating the configuration of a charging and power supplying device.

FIG. 4 is a perspective view schematically illustrating the configuration of a battery.

FIG. 5 is a cross-sectional view schematically illustrating the configuration of the battery.

FIG. 6 is a diagram schematically illustrating the configuration of a cooling device.

FIG. 7 is a front view schematically illustrating another configuration of the wind power generation system.

### DETAILED DESCRIPTION

The present disclosure will be described with reference to the drawings illustrating an embodiment thereof. For the sake of explanation, the dimensions ratio in the drawing may differ from actual ratio, and parts may be overemphasized or be omitted. In addition, for the sake of clarity of the drawings, members in contact may be illustrated in a manner separate from each other.

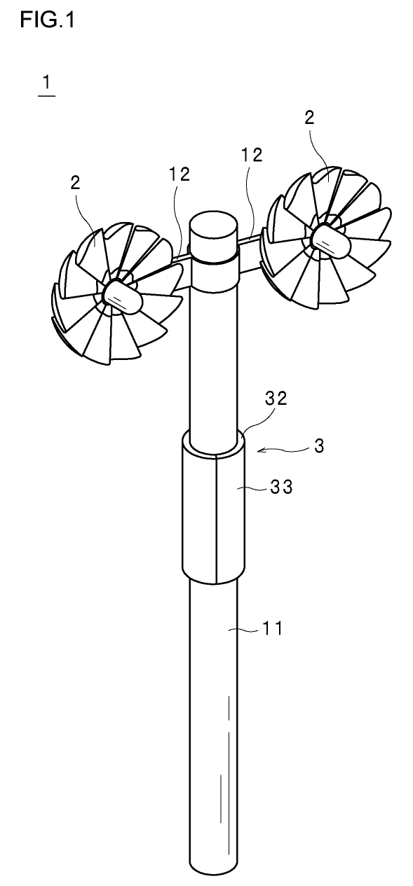

FIG. 1 is a perspective view roughly illustrating the configuration of a wind power generation system according to an embodiment.

The numeral 1 in the drawings represents a wind power generation system, and the wind power generation system 1 includes wind turbine generators 2 and a charging and power supplying device 3. The wind turbine generators 2 and the charging and power supplying device 3 are disposed on a columnar body 11.

The columnar body 11 is installed perpendicular to the ground.

The wind turbine generators 2 are supported by the columnar body 11 via supporters 12 attached to a tip portion of the columnar body 11. In FIG. 1, two supporters 12 extend from the tip portion of the columnar body 11 in opposite directions perpendicular to the longitudinal direction of the columnar body 11, and the wind turbine generators 2 are attached to the supporters 12.

Since the two wind turbine generators 2 have the same configuration, one of the two wind turbine generators 2 is described below. It should be noted that the number of wind turbine generators 2 supported by the columnar body 11 is not limited to two.

The charging and power supplying device 3 is attached midway lengthwise of the columnar body 11.

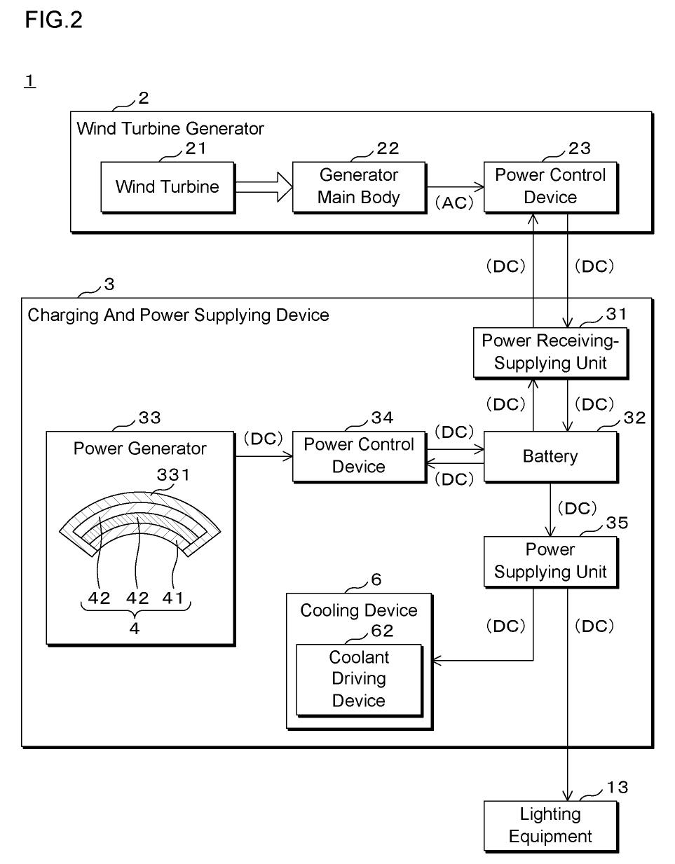

FIG. 2 is a block diagram roughly illustrating the configuration of the wind power generation system 1.

The wind turbine generator 2 is provided with a wind turbine 21, a generator main body 22 and a power control device 23.

The wind turbine 21 rotates in the wind. When the rotation of the wind turbine 21 is transmitted to the generator main body 22, the generator main body 22 generates electric power. The generator main body 22 generates alternating current by the power generation, and the generated alternating current is input to the power control device 23.

The power control device 23, which is a wind power generation control device, operates by receiving direct current from the charging and power supplying device 3. The power control device 23 has an AC/DC converter, and converts the alternating current received from the generator main body 22 into direct current and then supplies the direct current to the charging and power supplying device 3.

Note that the wind turbine generator 2 may be equipped with a built-in battery that is charged by the direct current output from the AC/DC converter contained in the power control device 23. Here, the power control device 23 can also operate by receiving direct current from the built-in battery.

The charging and power supplying device 3 is provided with a power receiving-supplying unit 31 and a battery 32.

The power receiving-supplying unit 31 is configured to be mounted with, for example, connection terminals and a charge/discharge control circuit for controlling the charge or discharge of the battery 32 on a circuit board. The power receiving-supplying unit 31 is electrically connected to the power control device 23 and the battery 32 and supplies the battery 32 with direct current received from the power control device 23. The battery 32 is charged by the fed direct-current power (i.e., power generated by the wind turbine generator 2). Here, the power receiving-supplying unit 31 functions as a power reception unit for receiving power from the wind turbine generator 2 (external generator when seen from the charging and power supplying device 3) and charging the battery 32. Note that the power receiving-supplying unit 31 may convert the alternating current generated by the generator main body 22 into direct current.

The power stored in the battery 32 is fed to the power control device 23 via the power receiving-supplying unit 31. Here, the power receiving-supplying unit 31 functions as a power supplying unit for supplying power from the battery 32 to the power control device 23 (external device when seen from the charging and power supplying device 3) of the wind turbine generator 2.

The charging and power supplying device 3 is provided with a power generator 33 and a power control device 34.

The power generator 33 includes a laminated body 4. The laminated body 4 is provided with a substrate 41 and multiple perovskite solar cells 42.

The substrate 41 has insulating properties and flexibility. One of the surfaces of the substrate 41 has light reflectivity. The one of the surfaces with light reflectivity of the substrate 41 is referred to as a reflective surface.

The perovskite solar cells 42 have a sheet-like form and have flexibility and light transmittance. Multiple perovskite solar cells 42 are connected in series with each other. Perovskite solar cells 42 may be connected in parallel to each other.

For example, in the case where the number of perovskite solar cells 42 is two, one of the perovskite solar cells 42 is stacked on the substrate 41 to entirely cover the reflective surface of the substrate 41. The other one of the perovskite solar cells 42 is stacked on the one of the perovskite solar cells 42 to entirely cover the one of the perovskite solar cells 42.

Note that the number of perovskite solar cells 42 may be three or more. The substrate 41 may be a solar cell that is electrically connected to the perovskite solar cells 42 but may different from the perovskite solar cells 42. The laminated body 4 may not necessarily have the substrate 41.

The laminated body 4 is arcuate (e.g., half-cylindrical) with the substrate 41 located inside. For example, the arcuate laminated body 4 can easily be obtained by curving a flat laminate formed of multiple perovskite solar cells 42 stacked on the substrate 41. Alternatively, the arc-shaped laminated body 4 can easily be obtained by stacking multiple perovskite solar cells 42 on the outer circumferential surface of the arcuately curved substrate 41.

The perovskite solar cells 42 receive light to generate direct current. In the case where light enters the outer circumferential surface of the laminated body 4, light enters and penetrates the perovskite solar cell 42 on the outer circumferential surface side of the laminated body 4 and reaches the perovskite solar cell 42 on the inner circumferential surface side of the laminated body 4. The light passing through the entire two perovskite solar cells 42 is reflected by the reflection plane of the substrate 41. The reflected light enters the perovskite solar cells 42 again.

Since the perovskite solar cells 42 have light transmittance, light penetrating one of the multiple perovskite solar cells 42 forming the laminated body 4 is received by another one of the perovskite solar cells 42 to generate electric power. The laminated structure of the perovskite solar cells 42 enables compact placement of the multiple perovskite solar cells 42.

Thin and light property of the perovskite solar cells 42 can achieve weight reduction of the charging and power supplying device 3.

As light to be incident on the laminated body 4, visible light is preferred, though ultraviolet rays or infrared rays may be allowable.

The power generator 33 is provided with a protective layer 331. The protective layer 331 covers the edge portions of the perovskite solar cells 42 constituting the laminated body 4 and the outer surface of the outermost perovskite solar cell 42. The protective layer 331 is transparent and thus is unlikely to hinder the perovskite solar cells 42 from generating electric power. Note that the protective layer 331 may also cover the substrate 41.

The power generator 33 may be provided with a carrier holding the laminated body 4. Here, the protective layer 331 may also cover the carrier.

The protective layer 331 protects the power generator 33 (especially perovskite solar cells 42) from contact with foreign objects. The protective layer 331 may be a paint that hardens after application, or a sheet made of synthetic resin or a thin plate.

The direct current produced through electric power generation by the perovskite solar cells 42 is input to the power control device 34.

The power control device 34 is a solar controller and controls the charging of the battery 32. The power control device 34 supplies the battery 32 with the direct current received from the perovskite solar cells 42. The battery 32 is charged by the fed direct-current power (i.e. power generated by the power generator 33, specifically power produced by the perovskite solar cells 42).

The charging and power supplying device 3 is provided with a power supplying unit 35. The power supplying unit 35 is configured to be mounted with connection terminals and a discharge control circuit controlling the discharge of the battery 32 on a circuit board, for example. The power supplying unit 35 is electrically connected to the battery 32 and lighting equipment 13 (external device) supported by the columnar body 11. The power stored in the battery 32 is fed to the lighting equipment 13 through the power supplying unit 35. The lighting equipment 13 is provided with an LED and lights up by the received direct current.

Note that the external device connected to the power supplying unit 35 may be electrical equipment other than the lighting equipment 13 (traffic signal, wireless communication device, security cameras or the like) or may be electrical equipment that is not supported by the columnar body 11 (e.g., electrical equipment placed in a house).

The power supplying unit 35, which contains a DC/AC inverter, may be configured to convert direct current from the battery 32 into alternating current and supply the alternating current to the external device connected to the power supplying unit 35. The power supplying unit 35 may be configured to supply power to the external device in a wireless manner.

Next, the structure for attachment of the charging and power supplying device 3 to the columnar body 11 is described.

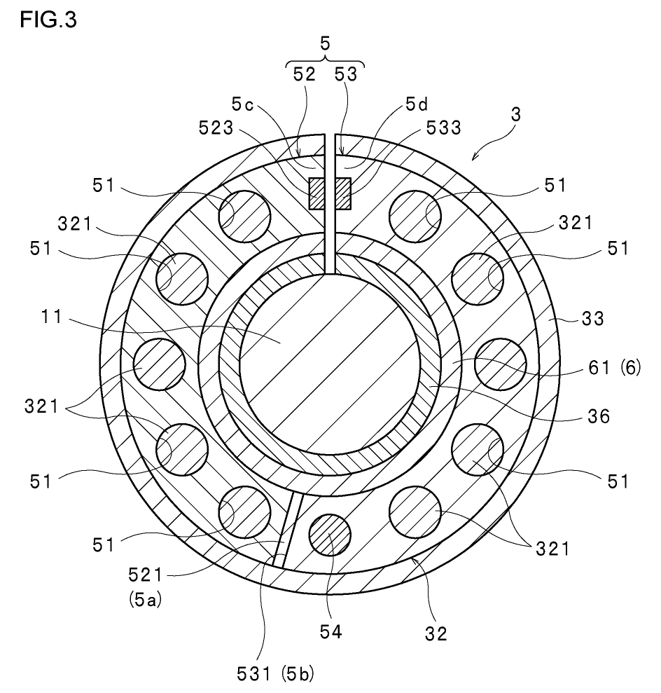

FIG. 3 is a cross-sectional view roughly illustrating the configuration of the charging and power supplying device 3.

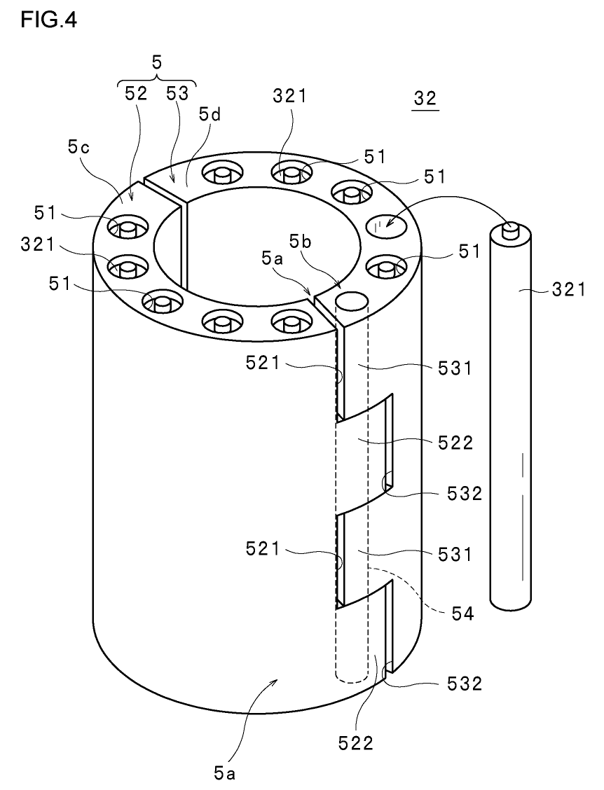

FIG. 4 is a perspective view roughly illustrating the configuration of the battery 32.

The battery 32 is tubular and coaxially covers the outer circumferential surface of the columnar body 11. For example, the battery 32 includes a tubular case 5, and the case 5 coaxially covers the outer circumferential surface of the columnar body 11 as illustrated in FIG. 3.

As illustrated in FIG. 4, the top end face of the case 5 is provided with multiple housing holes 51. Each of the housing holes 51 extends along the axial direction of the case 5. The multiple housing holes 51 are arranged in the circumferential direction of the case 5.

The battery 32 contains multiple cells 321. Each cell 321 is a columnar single cell capable of charging and discharging power. The cell 321 is housed in the housing hole 51 so that the axial direction of the cell 321 is oriented along the axial direction of the case 5. The cell 321 is housed in the housing hole 51 to be connected to a connection terminal (not illustrated) provided on the inner surface of the housing hole 51. The connection terminal may be located outside the housing hole 51. The connection terminal is for connecting the cells 321 circumferentially adjacent to each other by wire, or for charging and discharging the battery 32. Note that one housing hole 51 may contain multiple cells 321 connected to each other.

The charging and power supplying device 3 has a double-doored structure capable of opening outward to be attached to and detached from the columnar body 11, and is attached to the columnar body 11 in a closed position (with the columnar body 11 covered).

For example, the case 5 of the battery 32 includes two semi-cylindrical bodies 52, 53. One end portions 5a, 5b in the circumferential direction of the semi-cylindrical bodies 52, 53 are hinged to each other.

In the present embodiment, multiple recessed parts 521 and projected parts 522 are alternately arranged from the top in this order at the one end portion 5a of the semi-cylindrical body 52. The recessed part 521 has a shape rectangularly cut away from the one end 5a. The projected part 522 has a shape of a rectangular block that projects in the circumference direction of the case 5.

On the other hand, multiple projected parts 531 and recessed parts 532 are alternately arranged from the top in this order at the one end portion 5b of the semi-cylindrical body 53. The projected part 531 corresponds to the recessed part 521 while the recessed part 532 corresponds to the projected part 522.

The projected part of the semi-cylindrical body 53 is fit into the recessed part 521 of the semi-cylindrical body 52, while the projected part 522 of the semi-cylindrical body 52 is fit into the recessed part 532 of the semi-cylindrical body 53, which allows a hinge pin 54 to penetrate in up-and-down direction through all the projected parts 531 and the projected parts 522. As a result, the one end portions 5a, 5b of the semi-cylindrical bodies 52, 53 are hinged to each other.

FIG. 3 illustrates a cross section perpendicularly to the axial direction of the case 5 and through the projected parts 531.

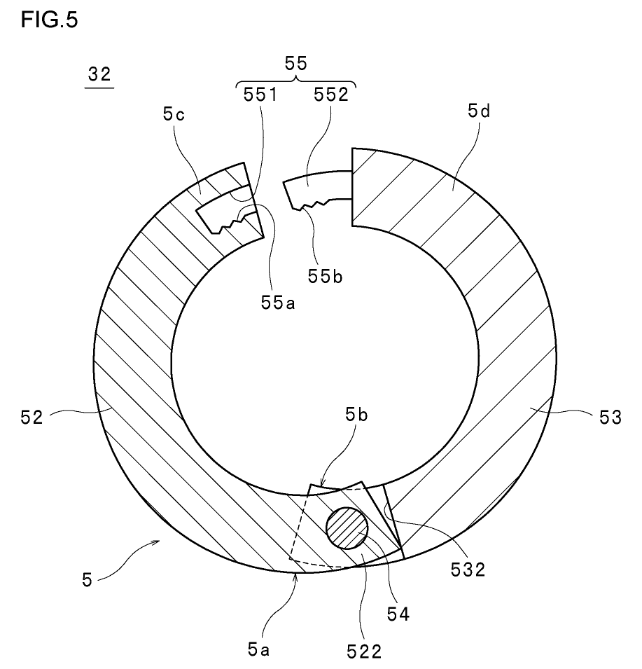

FIG. 5 is a cross-sectional view roughly illustrating the configuration of the battery 32. FIG. 5 illustrates a cross section taken perpendicularly to the axial direction of the case 5 and through the bottommost projected part 522.

The semi-cylindrical bodies 52 and 53 relatively oscillate about the hinge pin 54. When this occurs, the other end portions 5c and 5d in the circumferential direction of the semi-cylindrical bodies 52, 53 come into contact with or separate from each other.

The other end portions 5c and 5d of the semi-cylindrical bodies 52, 53 are separated from each other to open the battery 32.

When the battery 32 is opened, a void is formed between the other end portions 5c and 5d in the circumferential direction of the semi-cylindrical bodies 52, 53. The columnar body 11 can thus be inserted into and removed from the space surrounded by the semi-cylindrical bodies 52, 53 through the void.

On the other hand, as illustrated in FIG. 3, the other end portions 5c and 5d of the semi-cylindrical bodies 52, 53 come into contact or approach each other most closely to close the battery 32.

The hinge connection of the semi-cylindrical bodies 52, 53 is not limited to the above-mentioned configuration. For example, another hinge may be attached to run between the one end portions 5a, 5b of the semi-cylindrical bodies 52, 53.

The charging and power supplying device 3 is provided with a retainer for keeping the battery 32 closed. In the present embodiment, first and second retainers are exemplified.

The first retainer corresponds to magnets 523, 533. The magnet 523 is embedded in the end face of the other end portion 5c of the semi-cylindrical body 52 while the magnet 533 is embedded in the end face of the other end portion 5d of the semi-cylindrical body 53. The magnets 523, 533 have opposite polarities and are neodymium magnets, for example. The magnets 523, 533 having opposite polarities attract each other to keep the battery 32 closed.

Note that one of the magnets 523, 533 may be a magnetic material (e.g., a piece of iron).

The second retainer corresponds to a fixture 55 illustrated in FIG. 5. The fixture 55 includes an insertion hole 551 and an inserting part 552.

The insertion hole 551 is provided at the end face of the other end portion 5c of the semi-cylindrical body 52 so as not to interfere with the housing hole 51 of the semi-cylindrical body 52. At the inner circumferential surface of the insertion hole 551, saw blade-like projections (hereafter referred to as a saw blade 55a) are provided. The saw blade 55a projects from the inner circumferential surface of the insertion hole 551 toward the axis of the insertion hole 551 and has an inclined surface so that the amount of projection increases from the opening of the insertion hole 551 toward the bottom.

The inserting part 552 is a columnar and protrudes in the circumferential direction of the case 5 from the end face of the other end portion 5d of the semi-cylindrical body 53. At the outer circumferential surface of the inserting part 552, saw blade-like projections (hereafter referred to as a saw blade 55b) are provided. The saw blade 55b projects outwardly from the outer circumferential surface of the inserting part 552 and has an inclined surface so that the amount of projection increases from the tip end to the root end of the inserting part 552.

If the inserting part 552 is inserted into the insertion hole 551, the saw blade 55b contacts the saw blade 55a. Here, the saw blade 55a does not prevent the saw blade 55b from entering. On the other hand, if an external force working in the direction in which the inserting part 552 is pulled out of the insertion hole 551 is applied, the saw blade 55a is engaged with the saw blade 55b to prevent the saw blade 55b from coming off. This prevents unnecessary detachment of the inserting part 552 from the insertion hole 551. The battery 32 is thus kept closed.

The amount of projection from the other end portion 5d of the inserting part 552 may be variable. Alternatively, the inserting part 552 may be interchangeable with an inserting part 552 having a different axial length. If the inserting part 552 longer than the depth of the insertion hole 551 is used, the internal diameter of the battery 32 can be increased.

Note that by regulating the amount of insertion of the inserting part 552 into the insertion hole 551, the inner diameter of the battery 32 may be adjusted.

In the present embodiment, both magnets 523, 533 and the fixture 55 are used to each other, while either one of them may be used. Multiple magnets 523. 533 or multiple fixtures 55 may be arranged side by side along the axial direction of the case 5.

The retainer is not limited to the magnets 523, 533 and the fixture 55. For example, the retainer may be an annular metal fitting that coaxially surrounds the outer circumferential surface of the battery 32 and tightens the battery 32. The annular metal fitting is composed of two C-rings, for example, and is configured to make both ends of one of the C-rings attachable to and detachable from both ends of the other one of the C-rings.

In addition, the retainer may be a C-shaped ring having an appropriate flexibility, for example, and may be formed annular by inserting, into a concave portion provided at one end in the longitudinal direction, a convex portion provided at the other end. The amount of insertion of the convex portion into the concave portion adjusts the inner diameter of the retainer.

The battery 32 may be so configured that two separate semi-cylindrical bodies are formed cylindrically such that both circumferential ends of the one of the semi-cylindrical bodies face both circumferential ends of the other one of the semi-cylindrical bodies and may further be kept cylindrical with the retainer.

As illustrated in FIG. 3, the power generator 33 coaxially covers the outer circumferential surface of the case 5. Since the power generator 33 is flexible, it does not hinder the opening and closing of the battery 32.

While a single power generator 33 covers the outer circumferential surface of the case 5 in the present embodiment, multiple power generators 33 may be arranged side by side in the circumferential direction or the axial direction of the case 5.

The charging and power supplying device 3 is preferably provided with a cooling device 6 for cooling the battery 32.

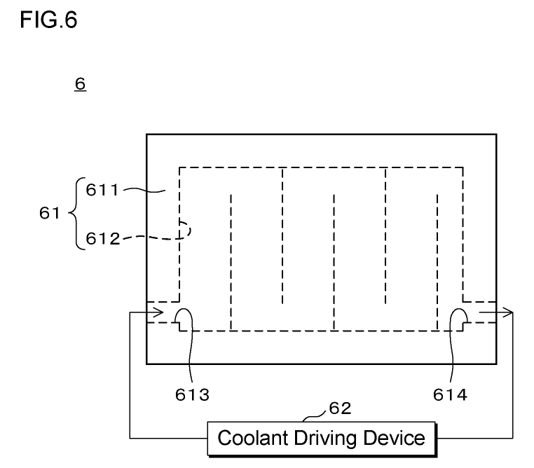

FIG. 6 is a diagram roughly illustrating the configuration of the cooling device 6.

The cooling device 6 is provided with a cooling member 61 and a coolant driving device 62, for example.

The cooling member 61 is composed of two superposed rectangular flexible sheets 611 between which a channel 612 for passing liquid coolant is formed. For example, the two sheets 611 are welded to each other linearly along the direction in which the coolant flows, to form the channel 612. The channel 612, which has an inlet 613 at one end of the longitudinal direction of the sheet 611 and an outlet 614 at the other end of the longitudinal direction of the sheet 611, meanders over generally full length of the transverse direction of the sheet 611 from the inlet 613 to the outlet 614.

The cooling member 61 is formed to be tubular to cover the inner circumferential surface of the case 5 of the battery 32 (see FIG. 3). Since the cooling member 61 is flexible, it does not hinder opening and closing of the battery 32. FIG. 6 illustrates the cooling member 61 in a spread state.

The coolant driving device 62 is provided with a pump, a Peltier element and the like. Pumping of the coolant by pump in the coolant driving device 62 makes the coolant pass through the channel 612 from the inlet 613 toward the outlet 614. While passing through the channel 612, the coolant is heated to high temperature due to the heat generated by the battery 32. The hot coolant is cooled by the Peltier element of the coolant driving device 62.

The coolant driving device 62 is powered from the battery 32 via the power supplying unit 35 (see FIG. 2).

The coolant driving device 62 is not limited in its location but may be placed in an interior space of the columnar body 11 if the columnar body 11 is hollow.

The cooling device 6 may be configured to dissipate heat by transferring the heat generated by the battery 32 to the columnar body 11. Here, it is desirable that the columnar body 11 is made of metal. For example, the cooling device 6 may be either integrated in the case 5 of the battery 32, or may include a first metal member in contact with the inner circumferential surface of the case 5 for receiving the heat generated by the battery 32 and a second metal member for passing the heat from the first metal member to the columnar body 11.

As illustrated in FIG. 3, it is desirable that the charging and power supplying device 3 is provided with a cushioning material 36 between the inner circumferential surface of the battery 32 and the outer circumferential surface of the columnar body 11.

The cushioning material 36 is a sheet-like sponge or a urethane foam sheet, for example, and is sandwiched between the cooling member 61 of the cooling device 6 and the outer circumferential surface of the columnar body 11 in the internal space of the case 5 of the battery 32. The cushioning material 36 functions as a spacer between the cooling member 61 and the columnar body 11 or as a protective member that protects the cooling member 61 from the friction with the columnar body 11.

If the cooling device 6 is not used, the cushioning material 36 is formed to be tubular to directly cover the inner circumferential surface of the case 5 of the battery 32. The cushioning material 36 functions as a spacer between the battery 32 and the columnar body 11 or as a protective member that protects the battery 32 from the friction with the columnar body 11.

The cushioning material 36 is flexible and does not hinder the opening or closing of the battery 32.

The power receiving-supplying unit 31, the power control device 34 and the power supplying unit 35 are not limited to their locations, but may preferably be configured to cover the top and bottom end faces of the battery 32 to downsize the charging and power supplying device 3.

Multiple charging and power supplying devices 3 in conjunction with each other may be connected to the columnar body 11.

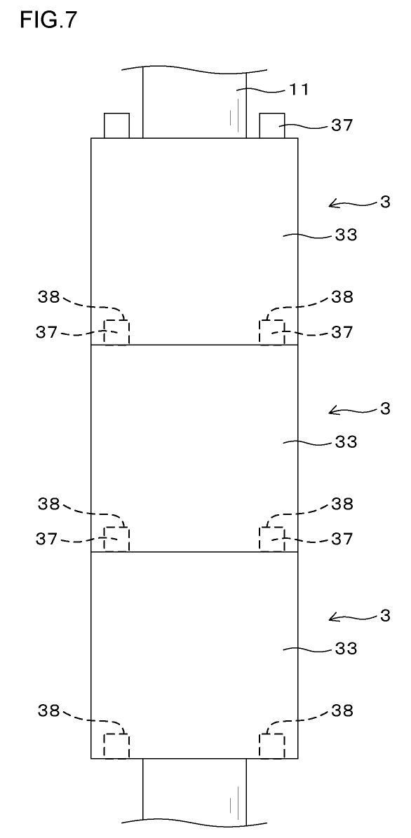

FIG. 7 is a front view roughly illustrating another configuration of the wind power generation system 1.

The wind power generation system 1 includes multiple charging and power supplying devices 3. Each of the charging and power supplying devices 3 is provided with multiple connection portions 37 and 38.

The connection portion 37 is, for example, a convex connection terminal provided in the power receiving-supplying unit 31 while the connection portion 38 is, for example, a concave connection terminal provided in the power receiving-supplying unit 31. The connection portion 37 is located on the top end surface side of the battery 32 while the connection portion 38 is located on the bottom end surface side of the battery 32. The connection portion 37 is fitted into the connection portion 38, to enable electrical connection between them.

The multiple charging and power supplying devices 3 are vertically arranged. By fitting the connection portion 37 of the lower charging and power supplying device 3 into the connection portion 38 of the upper charging and power supplying device 3, the two charging and power supplying devices 3 vertically arranged are electrically connected and coupled with each other. This makes it possible to electrically connect the upper and lower batteries 32.

If only two charging and power supplying devices 3 are connected, of the two charging and power supplying devices 3, the upper charging and power supplying device 3 does not need to have the connection portion 37 while the lower charging and power supplying device 3 does not need to have the connection portion 38.

According to the wind power generation system 1 as described above, the battery 32 is charged by the power generated by the power generator 33 or the power received from the wind turbine generator 2 via the power receiving-supplying unit 31. Hence, even in the case where the amount of power generated by either one of the power generator 33 or the wind turbine generator 2 is low, the battery 32 can be charged irrespective of the presence or absence of an external power supply. The power from the battery 32 is supplied to the lighting equipment 13 via the power supplying unit 35. Accordingly, convenience is improved.

The charging and power supplying device 3 is attached to the columnar body 11 supporting the wind turbine generators 2. Specifically, the tubular battery 32 coaxially covers the outer circumferential surface of the columnar body 11, and the power generator 33 covers the outer circumferential surface of the battery 32. This makes it possible to effectively use the dead space around the columnar body 11 when the wind turbine generator 2 and the charging and power supplying device 3 are placed close to each other.

The columnar body 11 may be configured to only support the lighting equipment 13 without supporting the wind turbine generators 2. Here, a power charging- supplying system including the charging and power supplying device 3 and lighting equipment 13 is configured.

A general columnar single battery can be used as a cell 321, which is thus easily available.

The charging and power supplying device 3 may be provided with a second power receiving-supplying unit that receives and supplies direct-current power from and to an external power control device (external device). The external power control device is a general power controller, for example. The power accumulated in the battery 32 is fed to the external power control device via the second power receiving-supplying unit and via the power receiving-supplying unit 31. The external power control device converts the received alternating current into direct current and supplies another electrical equipment with the direct current. In addition, the external power control device converts alternating current received from a commercial power utility (external power supply), for example, into direct current and supplies the charging and power supplying device 3 with the direct current. The second power charging-supplying unit supplies the battery 32 with the direct current received from the external power control device. The battery 32 is charged with the fed direct current power (i.e. power supplied from the external power supply).

The charging and power supplying device 3 is not limited to be attached to the already-installed columnar body 11 to cover the outer circumferential surface thereof. For example, when the columnar body 11 is installed, it may be inserted into the internal space of the battery 32. Here, the battery 32 does not need to have the opening and closing structure for attachment to and detachment from the columnar body 11.

The columnar body 11 to which the charging and power supplying device 3 is attached is not limited to support an external device but may be a supporting column that forms a fence, for example. The columnar body 11 is not limited to be vertically installed on the ground, but may be extended along the ground (e.g., handrail).

The perovskite solar cell 42 has an advantage of being able to generate electric power even under low light indoors. Therefore, even if the columnar body 11 to which the charging and power supplying device 3 is attached exists indoors or in adverse weather conditions, the battery 32 can be charged, which can further improve convenience.

### SUMMARY OF THE DISCLOSURE

A charging and power supplying device according to the present disclosure is configured to be attached to a columnar body. The charging and power supplying device comprises a tubular battery that coaxially covers an outer circumferential surface of the columnar body; a power generator that covers an outer circumferential surface of the battery; and a power supplying unit that supplies electric power from the battery to an external device. The battery is charged by electric power generated by at least the power generator.

In the present disclosure, the battery is charged by the electric power generated by at least the power generator. The battery can thus be charged irrespective of the presence or absence of an external power supply. The power from the battery is supplied to the external device via the power supplying unit. Accordingly, convenience is improved.

The charging and power supplying device is attached to the columnar body. More specifically, the tubular battery coaxially covers the outer circumferential surface of the columnar body, and the power generator covers the outer circumferential surface of the battery. This makes it possible to effectively use the dead space around the columnar body.

In the charging and power supplying device according to the present disclosure, the battery comprises a tubular case that coaxially covers the outer circumferential surface of the columnar body, and a plurality of cylindrical cells, and on an end surface of the case, a plurality of housing holes arranged in a circumferential direction of the case are provided, the cells are housed in the housing holes such that an axial direction of the cell is oriented along an axial direction of the case.

In the present disclosure, the battery is provided with a tubular case and multiple cells.

The case coaxially covers the outer circumferential surface of the columnar body. On the end surface of the case, multiple housing holes are provided to be arranged in a circumferential direction. The cylindrical cells are housed in the housing holes. The axial direction of the cell is oriented along the axial direction of the case.

This makes it possible to contain general cylindrical cells in the case with a simple structure and attach them to the columnar body via the case. On the inner surface of the housing hole, connection terminals that are electrically connected to the cells can be provided.

In the charging and power supplying device according to the present disclosure, the battery includes two semi-cylindrical bodies each having one end portion in a circumferential direction hinged to each other such that the other end portions come into contact with and separate from each other. The battery is configured to open and close by the other end portions coming into contact with and separating from each other. The charging and power supplying device further comprises a retainer configured to keep the battery closed.

In the present disclosure, the battery includes two semi-cylindrical bodies. The one end portions in the circumferential direction of the two semi-cylindrical bodies are hinged to each other. The two semi-cylindrical bodies relatively oscillate about the hinge, and the other end portions in the circumferential direction of the two semi-cylindrical bodies come into contact with and separate from each other, to make the battery open and close.

When the battery is opened, a void is formed between the other end portions in the circumferential direction of the two semi-cylindrical bodies. The columnar body can be inserted into and removed from the space surrounded by the two semi-cylindrical bodies through the void.

The retainer can keep the battery closed, so that the battery may be maintained in a state of coaxially covering the outer circumferential surface of the columnar body.

In the charging and power supplying device according to the present disclosure, the power generator includes a laminated body formed of a plurality of sheet-like perovskite solar cells stacked and curved in an arc, the laminated body coaxially covers the outer circumferential surface of the battery, and the battery is charged by electric power generated by at least the perovskite solar cells.

In the present disclosure, the power generator includes the laminated body. The laminated body is curved in an arc, and coaxially covers the outer circumferential surface of the battery.

The laminated body is formed of multiple layers of sheet-like perovskite solar cells stacked. Since the perovskite solar cells are flexible, a planar laminated body formed of multiple layers of sheet-like perovskite solar cells stacked is curved to easily obtain an arcuate laminated body.

The battery is charged by the electric power generated by at least the perovskite solar cells. The perovskite solar cells have an advantage of being able to generate electric power even under low light indoors. Therefore, even if the columnar body to which the charging and power supplying device is attached is present indoors or in adverse weather conditions, the battery can be charged, which can improve convenience.

The charging and power supplying device according to the present disclosure further comprises a transparent protective layer that covers at least an outer surface of the power generator to protect the power generator.

In the present disclosure, the protective layer protects the power generator. The protective layer covers at least the outer surface of the power generator. The protective layer is transparent and thus is unlikely to hinder the power generator from generating electric power if the power generator is provided with solar cells.

The charging and power supplying device according to the present disclosure further comprises a cushioning material positioned between an inner circumferential surface of the battery and the outer circumferential surface of the columnar body.

In the present disclosure, the cushioning material is positioned between the inner circumferential surface of the battery and the outer circumferential surface of the columnar body. The cushioning material functions as a spacer between the inner circumferential surface of the battery and the outer circumferential surface of the columnar body or as a protective member or the like that protects the battery from friction with the columnar body.

The charging and power supplying device according to the present disclosure further comprises a cooling device that cools the battery.

In the present disclosure, the cooling device cools the battery, which can prevent thermal runaway of the battery.

In the charging and power supplying device according to the present disclosure, electric power from the battery is supplied to the external device supported by the columnar body via the power supplying unit.

In the present disclosure, the power from the battery is supplied to the external device supported by the columnar body via the power supplying unit. The charging and power supplying device is attached to the columnar body that supports the external device. This makes it possible to effectively use the dead space around the columnar body when the external device and the charging and power supplying device are placed close to each other.

The charging and power supplying device according to the present disclosure further comprises a connection portion for connection with another charging and power supplying device configured to be attached to the columnar body, the connection portion being provided on at least one end side in an axial direction of the battery.

In the present disclosure, the connection portion is provided at least one end of the axial direction of the battery. When another charging and power supplying device is attached to the columnar body, multiple charging and power supplying devices aligned along the columnar body can be connected using the connection portions. The power generators or batteries contained in multiple charging and power supplying devices may be electrically connected to each other via the connection portions.

The charging and power supplying device according to the present disclosure further comprises a power reception unit that receives electric power from an external power generator to charge the battery.

In the present disclosure, the battery is charged by the electric power generated by the power generator or the electric power received from the external generator via the power reception unit. Therefore, the battery can be charged even in the case where the amount of power generated by either one of the power generator or the external generator is low. Accordingly, convenience can further be improved.

A wind power generation system according to the present disclosure comprises a wind turbine generator supported by a columnar body; and a charging and power supplying device configured to be attached to the columnar body. The charging and power supplying device comprises a tubular battery that coaxially covers an outer circumferential surface of the columnar body, a power generator that covers an outer circumferential surface of the battery, a power supplying unit that supplies electric power from the battery to an external device, and a power reception unit that receives electric power from the wind turbine generator to charge the battery. The battery is charged by electric power generated by at least the power generator.

In the present disclosure, the battery is charged by the electric power generated by the power generator or the electric power received from the wind turbine generator via the power reception unit. Hence, even in the case where the amount of power generated by either one of the power generator or the wind turbine generator is low, the battery can be charged irrespective of the presence or absence of an external power supply. The power from the battery is supplied to the external device via the power supplying unit. Thus, convenience is improved.

The charging and power supplying device is attached to the columnar body supporting the wind turbine generators. Specifically, the tubular battery coaxially covers the outer circumferential surface of the columnar body, and the power generator covers the outer circumferential surface of the battery. This makes it possible to effectively use the dead space around the columnar body when the wind turbine generator and the charging and power supplying device are placed close to each other.

The charging and power supplying device and wind power generation system according to the present disclosure can improve convenience.

It is noted that, as used herein and in the appended claims, the singular forms "a", "an", and "the" include plural referents unless the context clearly dictates otherwise.

It is to be noted that the disclosed embodiment is illustrative and not restrictive in all aspects. The scope of the present invention is defined by the appended claims rather than by the description preceding them, and all changes that fall within metes and bounds of the claims, or equivalence of such metes and bounds thereof are therefore intended to be embraced by the claims.

Moreover, independent claims and dependent claims stated in the scope of claims can be combined with each other in any combination, regardless of the citation format.

While the invention has been described in conjunction with various example structures outlined above and illustrated in the figures, various alternatives, modifications, variations, improvements, and/or substantial equivalents, whether known or that may be presently unforeseen, may become apparent to those having at least ordinary skill in the art. Accordingly, the example embodiments of the disclosure, as set forth above, are intended to be illustrative of the invention, and not limiting the invention. Various changes may be made without departing from the spirit and scope of the disclosure. Therefore, the disclosure is intended to embrace all known or later developed alternatives, modifications, variations, improvements, and/or substantial equivalents.

What is claimed is:

1. A charging and power supplying device configured to be attached to a columnar body, comprising:
a tubular battery that coaxially covers an outer circumferential surface of the columnar body;
a power generator that covers an outer circumferential surface of the battery; and
a power supplying unit that supplies electric power from the battery to an external device, wherein
the battery is charged by electric power generated by at least the power generator.

2. The charging and power supplying device according to claim 1, wherein
the battery comprises
a tubular case that coaxially covers the outer circumferential surface of the columnar body, and
a plurality of cylindrical cells, wherein
on an end surface of the case, a plurality of housing holes arranged in a circumferential direction of the case are provided,
the cells are housed in the housing holes such that an axial direction of the cell is oriented along an axial direction of the case.

3. The charging and power supplying device according to claim 1, wherein
the battery includes two semi-cylindrical bodies each having one end portion in a circumferential direction hinged to each other such that the other end portions come into contact with and separate from each other,
the battery is configured to open and close by the other end portions coming into contact with and separating from each other, and
further comprising a retainer configured to keep the battery closed.

4. The charging and power supplying device according to claim 1, wherein
the power generator includes a laminated body formed of a plurality of sheet-like perovskite solar cells stacked and curved in an arcuate manner,
the laminated body coaxially covers the outer circumferential surface of the battery, and
the battery is charged by electric power generated by at least the perovskite solar cells.

5. The charging and power supplying device according to claim 1, further comprising a transparent protective layer that covers at least an outer surface of the power generator to protect the power generator.

6. The charging and power supplying device according to claim 1, further comprising a cushioning material positioned between an inner circumferential surface of the battery and the outer circumferential surface of the columnar body.

7. The charging and power supplying device according to claim 1, further comprising a cooling device that cools the battery.

8. The charging and power supplying device according to claim 1, wherein electric power from the battery is supplied to the external device supported by the columnar body via the power supplying unit.

9. The charging and power supplying device according to claim 1, further comprising a connection portion for connection with another charging and power supplying device configured to be attached to the columnar body, the connection portion being provided on at least one end side in an axial direction of the battery.

10. The charging and power supplying device according to claim 1, further comprising a power reception unit that receives electric power from an external power generator to charge the battery.

11. A wind power generation system, comprising:
a wind turbine generator supported by a columnar body; and
a charging and power supplying device configured to be attached to the columnar body, wherein
the charging and power supplying device comprises
a tubular battery that coaxially covers an outer circumferential surface of the columnar body,
a power generator that covers an outer circumferential surface of the battery,
a power supplying unit that supplies electric power from the battery to an external device, and
a power reception unit that receives electric power from the wind turbine generator to charge the battery, wherein
the battery is charged by electric power generated by at least the power generator.
